(19) United States
(12) Patent Application Publication
(10) Pub. No.: US 2026/0248034 A1
(43) Pub. Date: Aug. 20, 2026

(54) PACKAGE STRUCTURE

(71) Applicant: Advanced Semiconductor Engineering, Inc., Kaohsiung (TW)

(72) Inventors: Jhao-Cheng CHEN, Kaohsiung (TW); Huang-Hsien CHANG, Kaohsiung (TW)

(73) Assignee: Advanced Semiconductor Engineering, Inc., Kaohsiung (TW)

(21) Appl. No.: 19/054,703

(22) Filed: Feb. 14, 2025

(51) Int. Cl. H01L 25/16; G02B 6/42; G02B 6/43; H01L 23/00; H01L 23/367; H01L 23/538; H05K 1/02; H10B 80/00; H10D 80/30

(52) U.S. Cl. CPC H10W 90/00; G02B 6/4212; G02B 6/4269; G02B 6/43; H10W 40/228; H10W 70/611; H10W 70/65; H10W 90/401; G02B 6/428; H05K 1/0203; H10B 80/00; H10D 80/30; H10W 74/10; H10W 74/15; H10W 80/312; H10W 80/327; H10W 90/288; H10W 90/724; H10W 90/734; H10W 90/794

(57) ABSTRACT

A package structure is provided. The package structure includes a photonic carrier, a circuit structure, and an optical transmission structure. The circuit structure includes a plurality of electronic components. The optical transmission structure separates the circuit structure from the photonic carrier and is configured to optically communicate between the electronic components. The photonic carrier is configured to support the circuit structure and the optical transmission structure and is configured to dissipate heat from the electronic components.

### BACKGROUND

### 1. Technical Field

The present disclosure relates generally to a package structure. Specifically, the present disclosure relates to a package structure including a photonic carrier.

### 2. Description of the Related Art

Currently, signal transmission between a package and components outside of the package is primarily conducted through optical fibers to overcome the limitations of insufficient bandwidth and high power consumption associated with electrical transmission. However, when the data transfer speed between multiple processors within the package also needs to be enhanced, the method of data transmission between processors within the package requires further improvement.

### SUMMARY

In one or more arrangements, a package structure includes a photonic carrier, a circuit structure, and an optical transmission structure. The circuit structure includes a plurality of electronic components. The optical transmission structure separates the circuit structure from the photonic carrier and is configured to optically communicate between the electronic components. The photonic carrier is configured to support the circuit structure and the optical transmission structure and is configured to dissipate heat from the electronic components.

In one or more arrangements, a package structure includes a photonic component, a plurality of electronic components, and a plurality of processing components. The electronic components are electrically connected to the photonic component. The processing components are electrically connected to each of the electronic components and configured to transmit signals through the photonic component.

In one or more arrangements, a package structure includes a plurality of first electronic components and a photonic component. The first electronic components are configured to generate heat dissipated through a plurality of thermal paths. The photonic component includes a plurality of optical channels. The optical channels are configured to transmit optical signals. The optical channels are substantially free from overlapping the thermal paths from a top view perspective.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a package structure in accordance with some arrangements of the present disclosure.

FIG. 1C is a cross-section of a portion of a package structure in accordance with some arrangements of the present disclosure.

FIG. 1D is a top view of a portion of a package structure in accordance with some arrangements of the present disclosure.

FIG. 2 is a top view of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, and FIG. 4M illustrate various stages of an example of a method for manufacturing a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

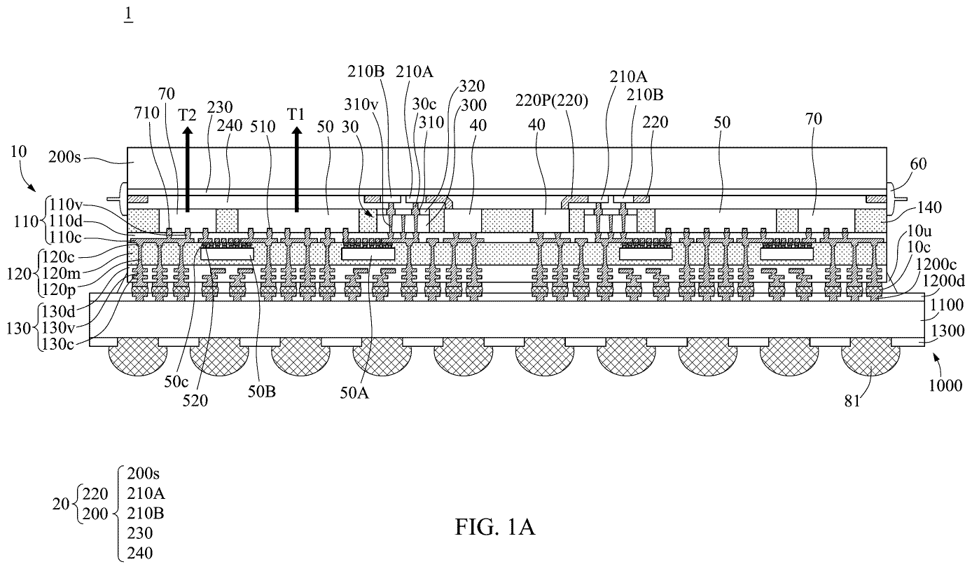

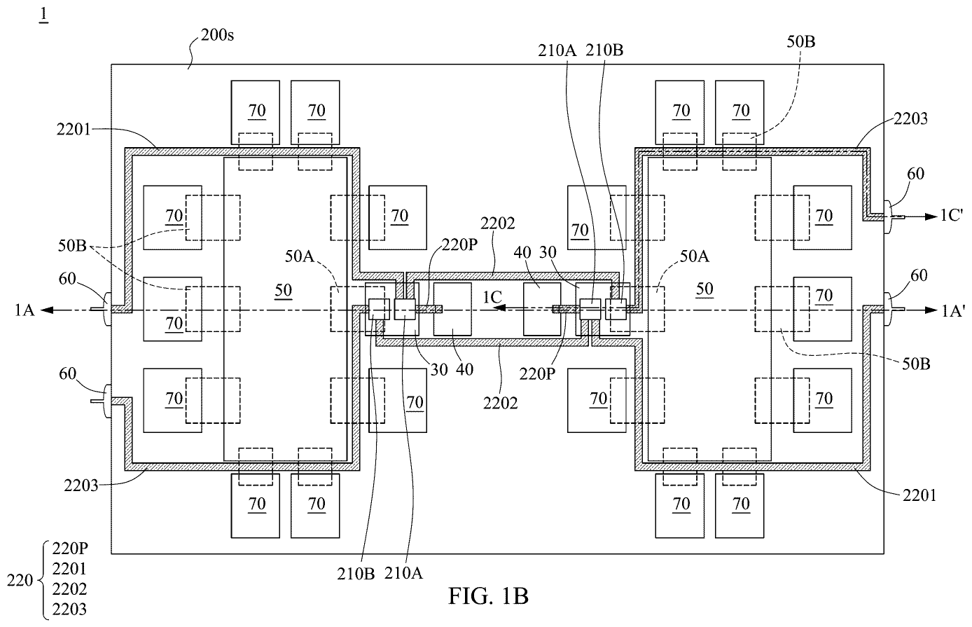

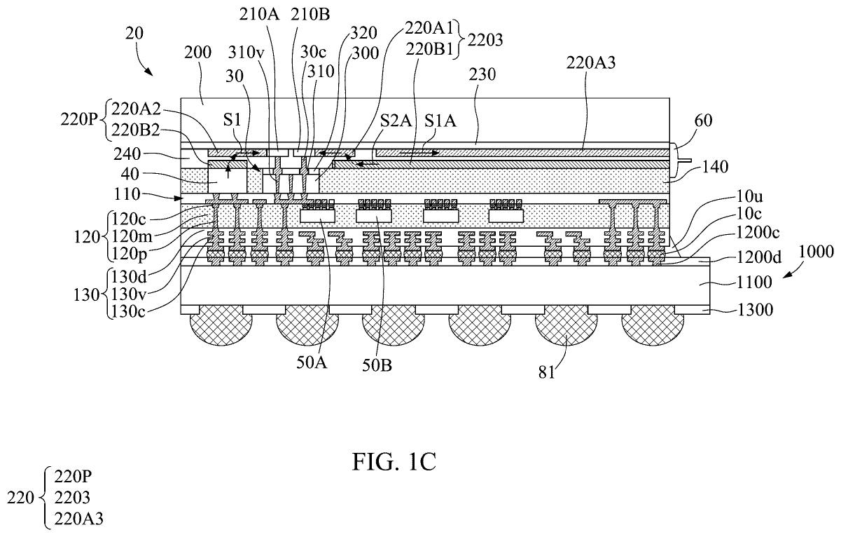

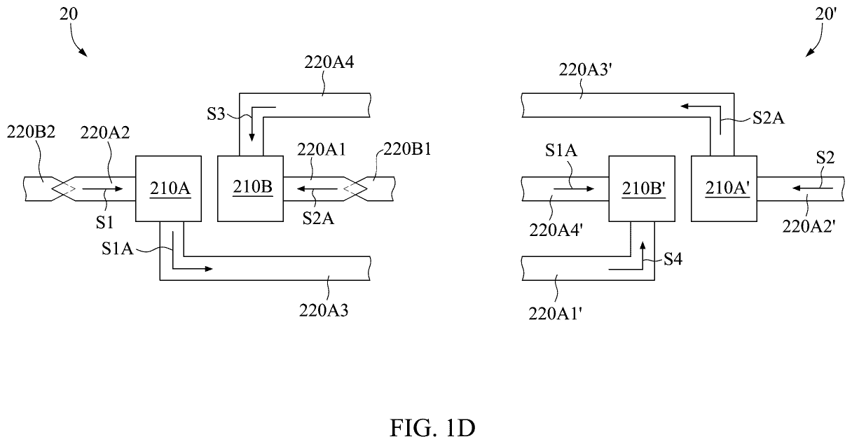

FIG. 1A is a cross-section of a package structure 1 in accordance with some arrangements of the present disclosure. FIG. 1B is a top view of a package structure 1 in accordance with some arrangements of the present disclosure. In some arrangements, FIG. 1A is a cross-section along a line 1A-1A′ in FIG. 1B. The package structure 1 may include a carrier 1000, a circuit structure 10, a photonic component 20, optical components 60, and electrical contacts 81.

The carrier 1000 may support the circuit structure 10, the photonic component 20, and the optical components 60. The carrier 1000 may include, for example, a printed circuit board, such as a paper-based copper foil laminate, a composite copper foil laminate, or a polymer-impregnated glass-fiber-based copper foil laminate. The carrier 1000 may include an interconnection structure, such as a plurality of conductive traces and a plurality of conductive vias. In some arrangements, the carrier 1000 includes a substrate, such as a semiconductor substrate, a ceramic substrate, a metal plate, an organic substrate, or a leadframe. In some arrangements, the carrier 1000 may include a two-layer substrate which includes a core layer and a conductive material and/or structure disposed on an upper surface and a bottom surface of the carrier 1000. In some arrangements, the carrier 1000 includes a core layer 1100, dielectric layers 1200d and 1300, and conductive elements 1200c. The dielectric layers 1200d and 1300 may include solder masks, and the conductive elements 1200c may include conductive pads and conductive vias.

The circuit structure 10 may be disposed over the electrically connected to the carrier 1000. In some arrangements, the circuit structure 10 includes electronic components 30, 40, 50, 50A, 50B, and 70, conductive structures 110, 120, and 130, and an encapsulant 140.

In some arrangements, the conductive structure 120 is disposed over and electrically connected to the conductive structure 130, and the conductive structure 110 is disposed over and electrically connected to the conductive structure 120. The conductive structures 110 and 120 may be referred to as redistribution structures.

In some arrangements, the conductive structure 110 includes a dielectric structure 110d, one or more conductive layers 110c in the dielectric structure 110d, and conductive vias 110v in the dielectric structure 110d and electrically connected to the conductive layers 110c. The dielectric structure 110d may include a plurality of dielectric layers. The conductive layers 110c may include conductive patterns, conductive pads, or the like.

In some arrangements, the conductive structure 120 includes an encapsulant 120m, conductive pillars 120p in the encapsulant 120m, and conductive pads 120c electrically connected to the conductive pillars 120p. In some arrangements, the conductive layer 110c is electrically connected to the conductive pillar 120p through the conductive pad 120c. The conductive pillar 120p may be configured to provide electrical signals or power from the carrier 1000 to the electronic components 30, 40, 50, and 70. The encapsulant 120m may include an epoxy resin having fillers dispersed therein, a molding compound (e.g., an epoxy molding compound or other molding compound), polyimide (PI), a phenolic compound or material, a polymer material with silicone dispersed therein, or a combination thereof.

In some arrangements, the conductive structure 130 includes a dielectric structure 130d, one or more conductive layers 130c in the dielectric structure 130d, and conductive vias 130v in the dielectric structure 130d and electrically connected to the conductive layers 130c. In some arrangements, the conductive pillar 120p is electrically connected to the conductive layer 130c through the conductive vias 130v. In some arrangements, the conductive structure 130 (or the redistribution structure) is electrically connected to connection elements 10c. In some arrangements, the conductive layers 130c is electrically connected to the conductive element 1200c of the carrier 1000 through the connection elements 10c. The connection elements 10c may be covered by a protective element 10u. The dielectric structure 130d may include a plurality of dielectric layers. The conductive layers 130c may include conductive patterns, conductive pads, or the like. The connection elements 10c may include conductive bumps or solder elements. The protective element 10u may include an underfill.

In some arrangements, the encapsulant 140 connects the conductive structure 110 to the photonic component 20. In some arrangements, the encapsulants 120m and 140 collectively construct an encapsulant structure that encapsulates the electronic components 30, 40, 50, 50A, 50B, and 70. The encapsulant 140 may include an epoxy resin having fillers dispersed therein, a molding compound (e.g., an epoxy molding compound or other molding compound), polyimide (PI), a phenolic compound or material, a polymer material with silicone dispersed therein, or a combination thereof.

In some arrangements, the electronic components 30 are disposed over and electrically connected to the conductive structure 110. In some arrangements, the electronic components 30 are electrically connected to the photonic component 20. In some arrangements, the electronic components 30 are configured to transmit electrical signals to or from the photonic component 20. In some arrangements, the electronic components 30 are encapsulated by the encapsulant 140. Each of the electronic components 30 may be or include an electronic integrated circuit (EIC). Each of the electronic components 30 may be or include an EIC element. Each of the electronic components 30 may include a logic circuit. Each of the electronic components 30 may include a modulator driver (DRV), a trans-impedance amplifier (TIA), or a combination thereof. The photonic component 20 and the electronic component 30 collectively may be configured for providing signal transmission for the electronic components 50 through optical communication.

In some arrangements, the electronic component 30 includes a carrier 300, a dielectric layer 320, conductive elements 310 in the dielectric layer 320, and conductive vias 310v penetrating the carrier 300 and electrically connected to the conductive elements 310. The carrier 300 may include a substrate. The conductive elements 310 may be conductive pads. The conductive elements 310 may be electrically connected to the photonic elements through connection elements 30c.

In some arrangements, the electronic components 40 are disposed over and electrically connected to the conductive structure 110. In some arrangements, the electronic components 40 are encapsulated by the encapsulant 140. In some arrangements, the electronic components 40 are optically coupled to the photonic component 20. Each of the electronic components 40 may be or include an optical source element. Each of the electronic components 40 may be or include a light-emitting element, e.g., a laser diode. In some arrangements, a distance between an optical channel (e.g., the optical channel 220P) of the photonic component 20 and an emission layer of the electronic component 40 may be about 0.02 μm to about 0.8 μm.

In some arrangements, the electronic components 50 are disposed over and electrically connected to the conductive structure 110. In some arrangements, conductive pads 510 of the electronic components 50 are electrically connected to the conductive vias 110v of the conductive structure 110. In some arrangements, the electronic components 50 are encapsulated by the encapsulant 140. In some arrangements, the electronic components 50 are electrically connected to the photonic component 20. In some arrangements, the electronic components 50 are electrically connected to the electronic components 30 and configured to transmit signals through the photonic component 20. Each of the electronic components 50 may be or include a processing component or a processing element, e.g., an ASIC, an FPGA, a GPU, or the like, or a combination thereof.

In some arrangements, the electronic component 50 is configured to transmit a command to the electronic component 30, the electronic component 30 is configured to receive the command, generate electrical signals in response to the command, and transmit the electrical signals to a photonic device of the photonic component 20, and the photonic device of the photonic component 20 is configured to convert the electrical signals to optical signals and transmit the optical signals to other components. The optical signals may be received by another photonic device of the photonic component 20 or to another photonic component 20 external to the package structure 1 and converted to electrical signals to be transmitted to a corresponding electronic component 50.

In some arrangements, active surfaces of the electronic components 30 and active surfaces of the electronic components 50 face opposite directions. In some arrangements, the active surfaces of the electronic components 30 face the photonic carrier 200, and the active surfaces of the electronic components 50 face the circuit structure 10. In some arrangements, the photonic component 20 and the conductive structures 110 and 130 (or the redistribution structures) are at opposite sides of the electronic components 30 and 50.

In some arrangements, the electronic components 50A are disposed over and electrically connected to the conductive structure 110. In some arrangements, conductive pads 520 of the electronic components 50A are electrically connected to the conductive layer 110c of the conductive structure 110 through connection elements 50c (e.g., conductive bumps). In some arrangements, the electronic components 50A are encapsulated by the encapsulant 120m. In some arrangements, at least two of the electronic components 30, 50, and 70 are electrically connected to each other through the electronic component 50A. In some arrangements, the electronic component 50A is configured to electrically communicate the electronic component 30 with the electronic component 50. In some arrangements, electrical signals from the electronic component 50 may be transmitted to the electronic component 30 through the electronic component 50A, the conductive structure 110, and the conductive vias 310v. In some arrangements, the electronic components 50A are or include bridge elements.

In some arrangements, the electronic components 50B are disposed over and electrically connected to the conductive structure 110. In some arrangements, conductive pads 520 of the electronic components 50B are electrically connected to the conductive layer 110c of the conductive structure 110 through connection elements 50c (e.g., conductive bumps). In some arrangements, the electronic components 50B are encapsulated by the encapsulant 120m. In some arrangements, at least two of the electronic components 30, 50, and 70 are electrically connected to each other through the electronic component 50B. In some arrangements, the electronic component 50B is configured to electrically communicate the electronic component 70 with the electronic component 50. In some arrangements, electrical signals may be transmitted between the electronic component 50 and the electronic component 70 through the electronic component 50B and the conductive structure 110. In some arrangements, the electronic components 50B are or include bridge elements.

In some arrangements, the electronic components 70 are disposed over and electrically connected to the conductive structure 110. In some arrangements, conductive pads 710 of the electronic components 70 are electrically connected to the conductive vias 110v of the conductive structure 110. In some arrangements, the electronic components 70 are encapsulated by the encapsulant 140. Each of the electronic components 70 may be or include a storage element. Each of the electronic components 70 may be or include a high bandwidth memory (HBM).

The photonic component 20 may be disposed over and electrically connected to the circuit structure 10. The photonic component 20 may be configured to optically couple to one or more optical components (e.g., the optical component 60). The photonic component 20 may be or include a photonic integrated circuit (PIC), a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof.

In some arrangements, the photonic component 20 includes a carrier 200s, photonic elements or devices (e.g., optical modulators 210A and photodetectors 210B), an optical transmission structure 220, and dielectric layers 230 and 240. The carrier 200s may include a semiconductor substrate. The optical transmission structure 220 may include optical waveguides or optical channels (e.g., silicon or silicon nitride). The dielectric layers 230 and 240 may include dielectric cladding materials (e.g., silicon oxide). The dielectric layers 230 and 240 may be referred to as cladding layers. In some arrangements, the refractive index of the optical transmission structure 220 is greater than the refractive index of the dielectric layers 230 and 240. The photonic elements or devices (e.g., the optical modulators 210A and the photodetectors 210B) may be disposed over the carrier 200s. The carrier 200s, the photonic elements or devices (e.g., the optical modulators 210A and the photodetectors 210B), and the dielectric layers 230 and 240 may collectively construct a photonic carrier 200.

In some arrangements, the photonic carrier 200 is configured to support the circuit structure 10 and the optical transmission structure 220 and dissipate heat from the electronic components 30, 40, 50, 50A, 50B, and 70. In some arrangements, a lateral side of the photonic carrier 200 is substantially aligned with a lateral side of the optical transmission structure 220. In some arrangements, the lateral side of the photonic carrier 200 is substantially aligned with a lateral side of the conductive structure 110 (or the redistribution structure). In some arrangements, the lateral side of the photonic carrier 200 is substantially aligned with a lateral side of the conductive structure 130 (or the redistribution structure). In some arrangements, the lateral side of the photonic carrier 200 is substantially aligned with a lateral side of the encapsulant structure (the combined structure including the encapsulants 120m and 140).

In some arrangements, the optical modulators 210A are configured to convert electrical signals from the electronic components 30 to optical signals.

In some arrangements, the optical transmission structure 220 separates the circuit structure 10 from the photonic carrier 200 and is configured to optically communicate between the electronic components (e.g., the electronic components 30, 50, and/or 70). In some arrangements, the optical transmission structure 220 is optically coupled to the photonic elements (e.g., the optical modulators 210A and the photodetectors 210B) and is configured to optically communicate between the electronic components 50 (or the processing components).

The optical components 60 may be optically coupled to the photonic component 20. In some arrangements, the photonic component 20 is configured to optically couple to at least one of the optical components 60. In some arrangements, the optical component 60 is disposed at an edge of the optical transmission structure 220. The optical component 60 is configured to provide inter-package optical connection or communication. The optical component 60 may be referred to as an optical coupling component. In some arrangements, the optical component 60 includes one or more optical fibers. In some arrangements, the optical component 60 is or includes an optical fiber array unit (FAU).

The electrical contacts 81 may be disposed on the conductive structure 130 and provide electrical connections between the package structure 1 and external components (e.g. external circuits or circuit boards). In some embodiments, the electrical contacts 81 include controlled collapse chip connection (C4) bumps, a ball grid array (BGA), or a land grid array (LGA).

Referring to FIGS. 1A and 1B, in some arrangements, projections of the electronic components 30 on a carrier (e.g., the carrier 1000) are within a projection of the photonic component 20 on the carrier from a top view perspective. In some arrangements, projections of the electronic components 50 on a carrier (e.g., the carrier 1000) are within a projection of the photonic component 20 on the carrier from a top view perspective.

In some arrangements, the electronic components 50 and 70 are configured to generate heat that is dissipated through thermal paths T1 and T2. In some arrangements, an area of the thermal path T1 substantially covers an area of the electronic components 50 from a top view perspective. In some arrangements, an area of the thermal path T2 substantially covers an area of the electronic components 70 from a top view perspective.

Referring to FIG. 1B, in some arrangements, the optical transmission structure 220 includes optical channels 2201, 2202, 2203, and 220P. In some arrangements, the optical channels 2201, 2202, 2203, and 220P are substantially free from overlapping the thermal paths T1 and T2 from a top view perspective. In some arrangements, the optical channels 2201, 2202, 2203, and 220P are substantially free from overlapping the electronic components 50 and 70 from a top view perspective.

In some arrangements, the photonic carrier 200 partially overlaps the thermal paths T1 and T2 from a top view perspective. In some arrangements, the photonic carrier 200 includes a first portion passed by the thermal paths T1 and T2. In some arrangements, the photonic carrier 200 includes a second portion different from the first portion and including the optical channels 2201, 2202, 2203, and 220P. In some arrangements, the optical channels 2201 and 2203 extend around an edge of at least one of the electronic components 50 from the top view perspective. In some arrangements, the optical channels 2202 extending between at least two of the electronic components 50 from the top view perspective. In some arrangements, the optical channels 2202 partially overlap the electronic components 30 from a top view perspective. In some arrangements, the optical channel 220P partially overlaps at least one of the electronic components 30 and at least one of the electronic components 40 (or the optical source elements) from the top view perspective.

In some arrangements, the optical channel 2201 optically couples one of the photonic elements (e.g., the optical modulator 210A) to one of the optical components 60 (or the optical coupling components). In some arrangements, the optical channel 2202 optically couples the one of the photonic elements (e.g., the optical modulator 210A) to another one of the photonic elements (e.g., the photodetector 210B). In some arrangements, at least two of the photonic elements are optically coupled to each other by at least one of the optical channel 2202. In some arrangements, the optical channel 220P optically couples the one of the photonic elements (e.g., the optical modulator 210A) to the electronic component 40 (or the optical source element). In some arrangements, the optical channel 2203 optically couples one of the photonic elements (e.g., the photodetector 210B) to one of the optical components 60 (or the optical coupling components).

In some arrangements, the photodetector 210B may receive an optical signal from the optical component 60 through the optical channel 2203 or from an optical modulator 210A corresponding to another processing component (e.g., the electronic component 50) through the optical channel 2202. In some arrangements, the photodetector 210B may be configured to convert the received optical signal to an electrical signal and transmit the electrical signal to the EIC element (e.g., the electronic component 30) and then the processing component (e.g., the electronic component 50). In some arrangements, the optical modulator 210A may be optically coupled to the optical source element (e.g., the electronic component 40) and convert an electrical signal from the EIC element (e.g., the electronic component 30) to a modulated optical signal and transmit the modulated optical signal to the optical component 60 through the optical channel 2201 or to a photodetector 210B corresponding to another processing component (e.g., the electronic component 50) through the optical channel 2202.

In some arrangements, a signal path may start from an electronic component 50, pass the conductive structure 110, the electronic component 50A, the conductive structure 110 again, the electronic component 30, the photonic carrier 200, another electronic component 30, another electronic component 50A, the conductive structure 110 again sequentially, and ends at another electronic component 50.

According to some arrangements of the present disclosure, one photonic carrier supports and is electrically connected to a plurality of electronic components and a plurality of processing components, and an optical transmission structure is configured to optically communicate between the electronic components and/or the processing components. Therefore, the signal transmission between the electronic components and/or the processing components within one package structure can be achieved by optical communication (i.e., intra-package optical connection or communication). As such, the transmission speed can be increased significantly, and the signal integrity can be improved since signal loss is reduced. For example, for transmission between processing components separated from one another by a distance greater than 5 mm or from about 5 mm to about 35 mm (e.g., for a package structure having a size of about 6600 mm²), a data rate of greater than 50 Gbps can be achieved.

In addition, according to some arrangements of the present disclosure, the photonic carrier is configured to dissipate heat from the electronic components and the processing components. Therefore, the photonic carrier can not only provide conversion between electrical signals and optical signals but also serve as a heat sink to increase the heat dissipation ability of the package structure as well as supporting the electronic components to increase the structural strength of the entire package structure.

Moreover, according to some arrangements of the present disclosure, one photonic carrier is integrated with multiple electronic components (e.g., EIC elements) to construct an integrated optical engine for signal transmission between multiple processing components. Therefore, with the reduced number of the optical engine disposed in one package structure, the heat dissipation effect can be increased, which is advantageous to the performance of the package structure.

FIG. 1C is a cross-section of a portion of a package structure 1 in accordance with some arrangements of the present disclosure. In some arrangements, FIG. 1C shows a cross-section of a portion (e.g., along a line 1C-1C′) of the package structure 1 illustrated in FIG. 1A with some differences therebetween described as follows.

In some arrangements, the optical transmission structure 220 includes at least optical channels 220P, 2203, and 220A3. In some arrangements, the optical channel 2203 includes an upper channel 220A1 and a lower channel 220B1. In some arrangements, the optical channel 220P includes an upper channel 220A2 and a lower channel 220B2.

In some arrangements, an optical signal is optically coupled from the electronic component 40 to the optical modulator 210A along a path S1 passing through the lower channel 220B2 and the upper channel 220A2 to provide an optical source to the optical modulator 210A. In some arrangements, the optical modulator 210A is configured to convert an electrical signal transmitted from the electronic component 30 to a modulated optical signal to the optical component 60 along a path S1A passing through the optical channel 220A3. In some arrangements, the photodetector 210B is configured to receive an optical signal from the optical component 60 along a path S2A passing through the lower channel 220B1 and the upper channel 220A1. The lower channel may have a tapered end, the upper channel may have a tapered end vertically overlapping the tapered end of the lower channel, and the lower channel and the upper channel may be optically coupled to each other by evanescent coupling.

According to some arrangements of the present disclosure, at least some of the optical channels of the optical transmission structure 220 may include an upper channel and a lower channel. The optical channels are free from overlapping the electronic components so as to avoid overlapping thermal paths to reduce the risks of being damaged by heat, such that the area for arranging the optical channels may be reduced. With the multi-layered optical channels of the optical transmission structure, the optical transmission region is increased, the optical coupling efficiency can be increased, and the optical transmission speed can be increased accordingly.

FIG. 1D is a top view of a portion of a package structure in accordance with some arrangements of the present disclosure. In some arrangements, FIG. 1D shows a top view of a portion of the package structure 1 illustrated in FIG. 1A with some differences therebetween described as follows. In some arrangements, FIG. 1C shows a cross-section of a portion of the structure illustrated in FIG. 1D.

In some arrangements, another photonic component 20′ of another package structure may be optically coupled to the photonic component 20 of the package structure 1.

In some arrangements, an optical signal is optically coupled to the optical modulator 210A′ along a path S2 passing through the lower channel 220A2′ to provide an optical source to the optical modulator 210A′. In some arrangements, the optical modulator 210A′ is configured to convert an electrical signal transmitted from an electronic component to a modulated optical signal and transmit the modulated optical signal along the path S2A passing through the optical channel 220A3′. The path S2A further passes through the lower channel 220B1 and the upper channel 220A1 so as to transmit the modulated optical signal from the photonic component 20′ to the photonic component 20.

In some arrangements, the photodetector 210B′ is configured to receive an optical signal from the optical component 60 along the path S1A passing through an optical channel 220A4′. The path S1A further passes through the lower channel 220B1 and the upper channel 220A1 so as to receive the optical signal (i.e., the modulated optical signal) from the photonic component 20 to the photonic component 20′. In some arrangements, the photodetector 210B′ of the photonic component 20′ is further configured to receive an optical signal along a path S4 passing through an optical channel 220A1′.

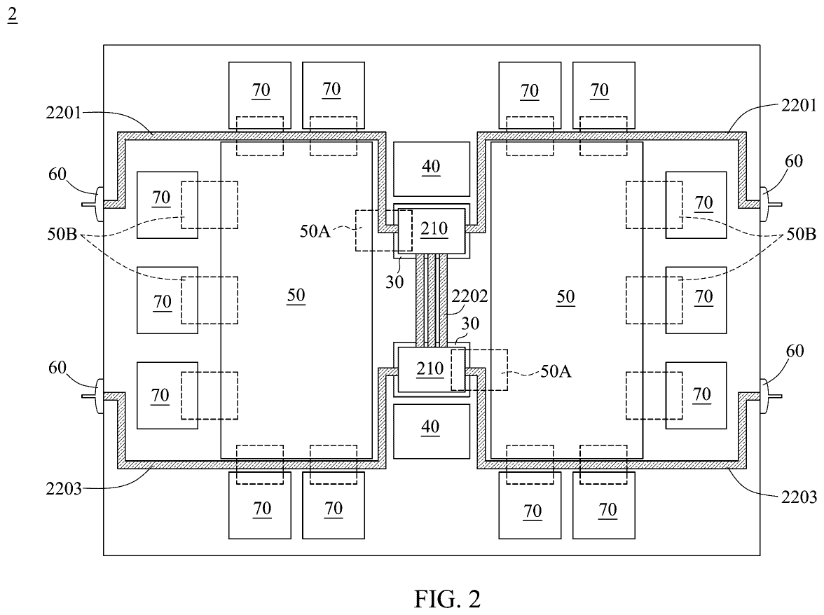

FIG. 2 is a top view of a package structure 2 in accordance with some arrangements of the present disclosure. The structure shown in FIG. 2 is similar to the structure shown in FIG. 1B, and the differences therebetween are described as follows.

In some arrangements, the package structure 2 includes photonic elements 210 optically coupling to the optical channels 2201, 2202, and 2203. In some arrangements, each of the photonic elements 210 includes an optical modulator and a photodetector.

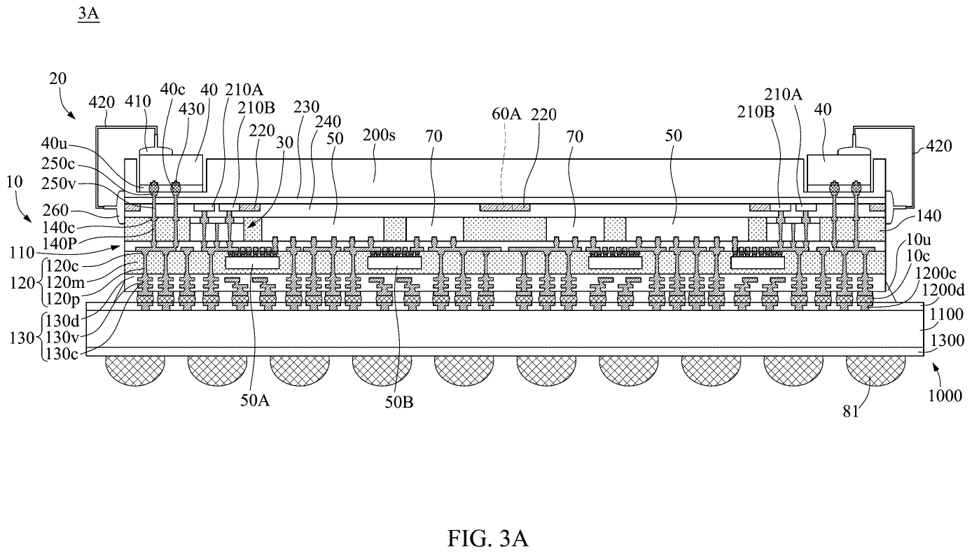

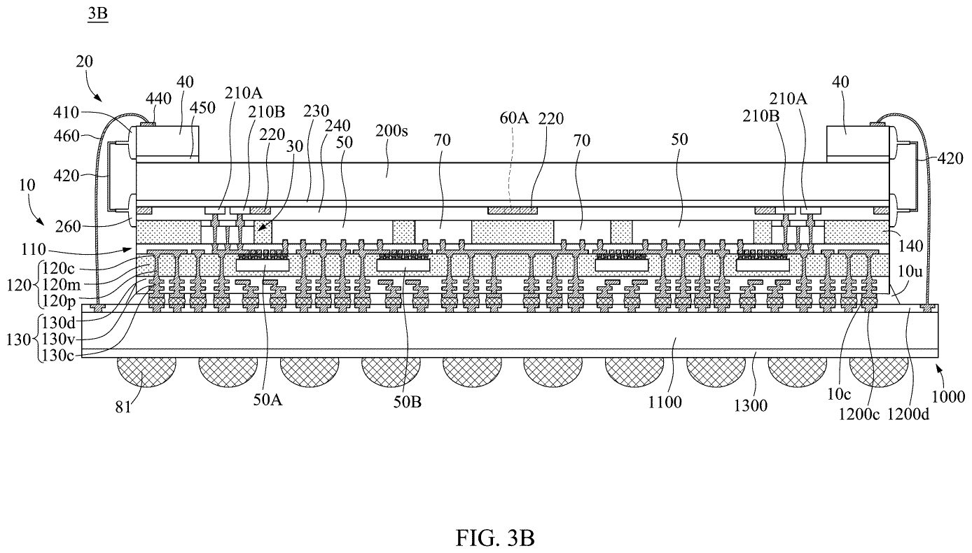

FIG. 3A is a cross-section of a package structure 3A in accordance with some arrangements of the present disclosure. The structure shown in FIG. 3A is similar to the structure shown in FIG. 1A, and the differences therebetween are described as follows.

In some arrangements, the circuit structure 10 further includes conductive pillars 140P and conductive pads 140c encapsulated by the encapsulant 140. In some arrangements, the conductive pads 140c are electrically connected to the conductive structure 110 through the conductive pillars 140P.

In some arrangements, the photonic component 20 further includes conductive elements 250c (e.g., conductive pads or conductive vias), conductive pillars 250v electrically connecting the conductive elements 250c to the conductive pads 140c, and an optical terminal 260 (e.g., an edge coupler) optically coupled to the optical transmission structure 220. In some arrangements, the conductive elements 250c are within the carrier 200s, and the conductive pillars 250v penetrate the dielectric layers 230 and 240.

In some arrangements, the electronic component 40 is disposed in a recess of the carrier 200s of the photonic component 20. The electronic component 40 may be referred to as an external optical source module. In some arrangements, the electronic component 40 includes an optical terminal 410 optically coupling to the optical terminal 260 through the optical wire 420. The optical wire 420 may be or include one or more optical fibers. In some arrangements, the electronic component 40 is configured to provide an optical signal to the optical modulator 210A through the optical wire 420 and the optical transmission structure 220. In some arrangements, the electronic component 40 includes conductive pads 430 electrically connected to the conductive elements 250c through connection elements 40c covered by a protective element 40u.

In some arrangements, the optical transmission structure 220 includes a portion 60A which is optically coupled to an optical component 60 (not shown in FIG. 3A).

FIG. 3B is a cross-section of a package structure 3B in accordance with some arrangements of the present disclosure. The structure shown in FIG. 3B is similar to the structure shown in FIG. 1A, and the differences therebetween are described as follows.

In some arrangements, the electronic component 40 is attached to a surface of the carrier 200s of the photonic component 20 through an adhesive element 450. The electronic component 40 may be referred to as an external optical source module. In some arrangements, the electronic component 40 includes an optical terminal 410 (e.g., an edge coupler) optically coupling to the optical terminal 260 through the optical wire 420. In some arrangements, the electronic component 40 is configured to provide an optical signal to the optical modulator 210A through the optical wire 420 and the optical transmission structure 220. In some arrangements, the electronic component 40 includes a conductive pad 440 electrically connected to the conductive element 1200c of the carrier 1000 through a conductive wire 460.

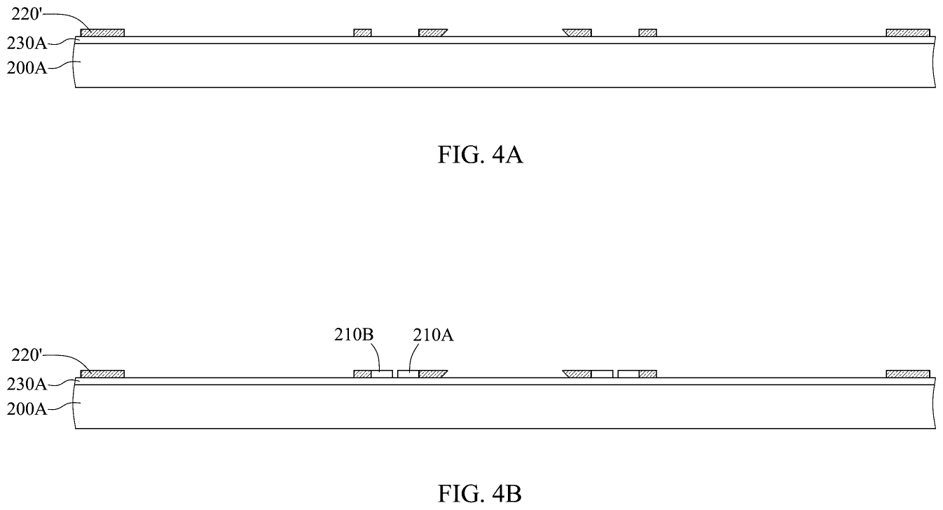

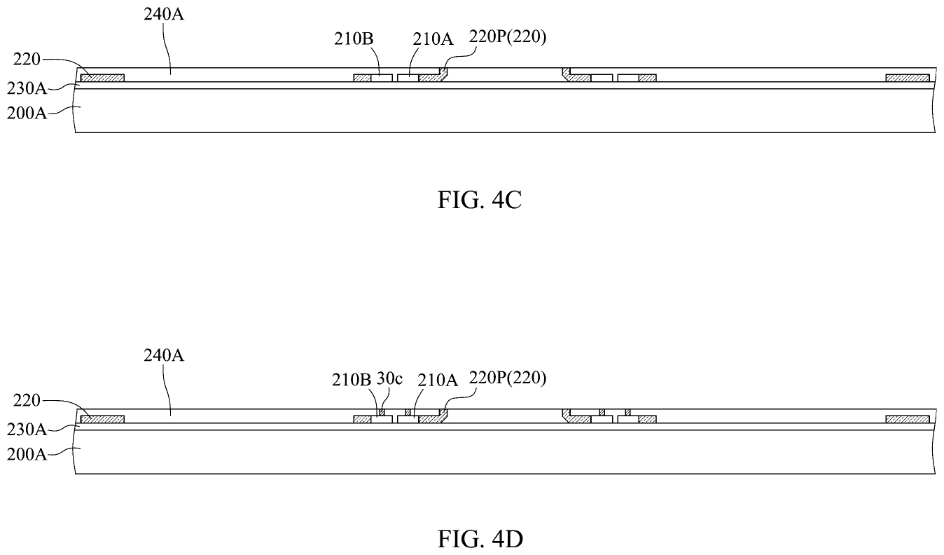

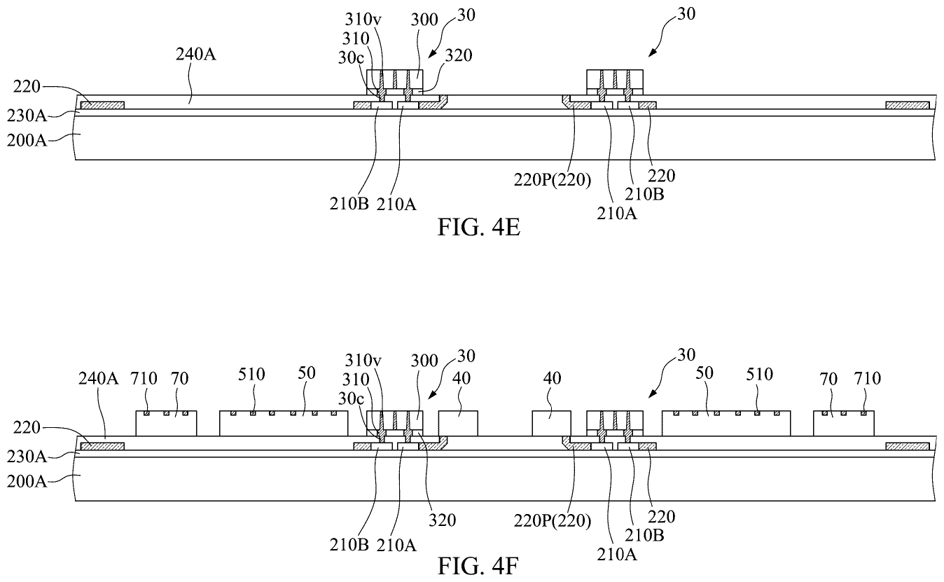

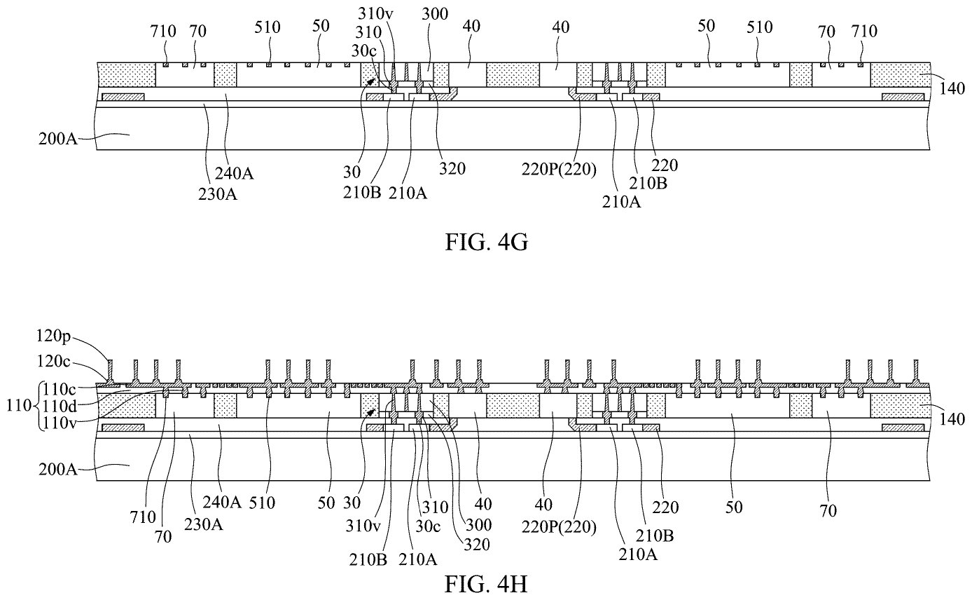

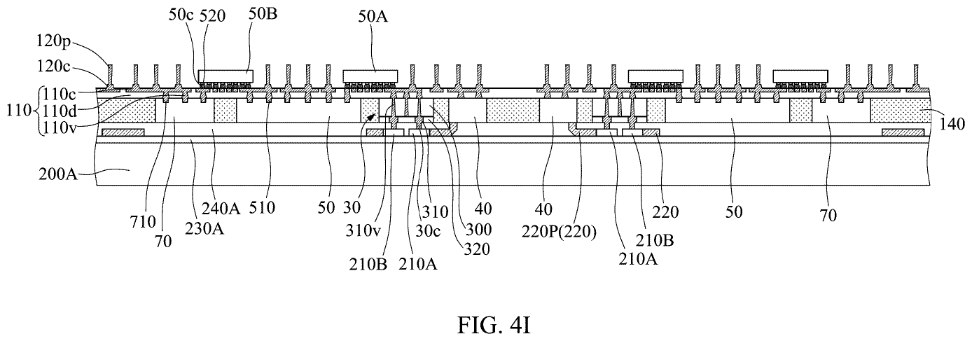

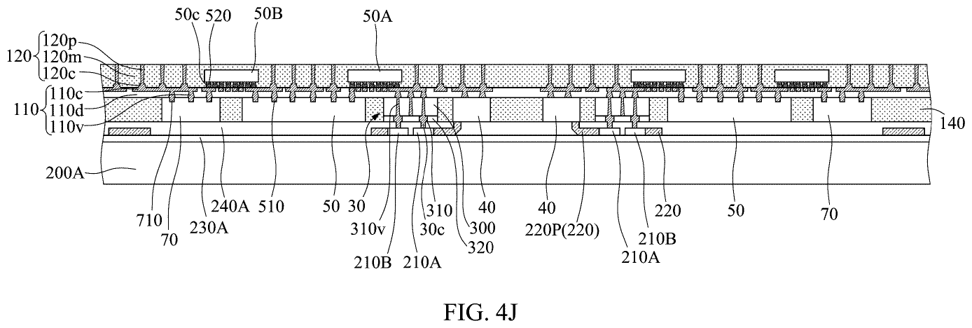

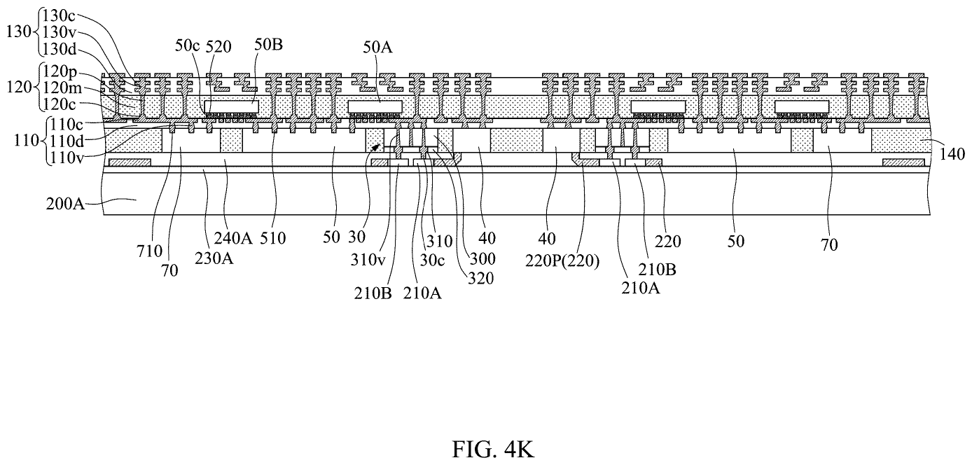

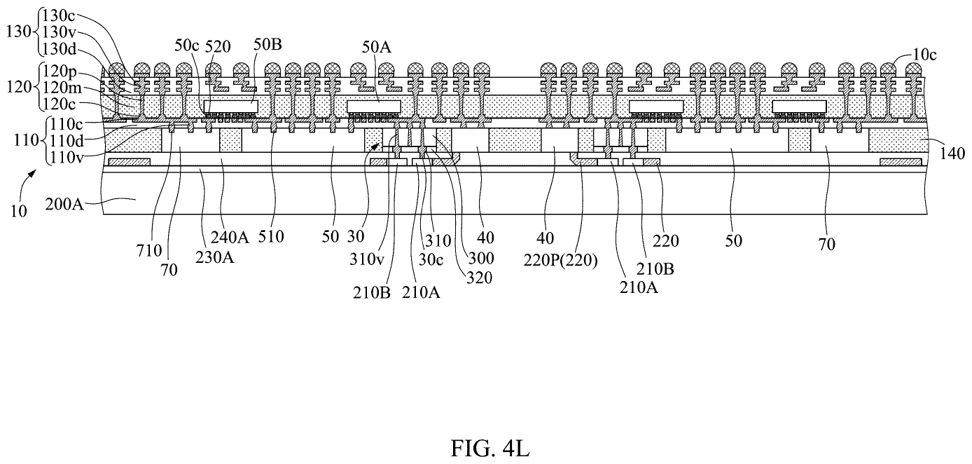

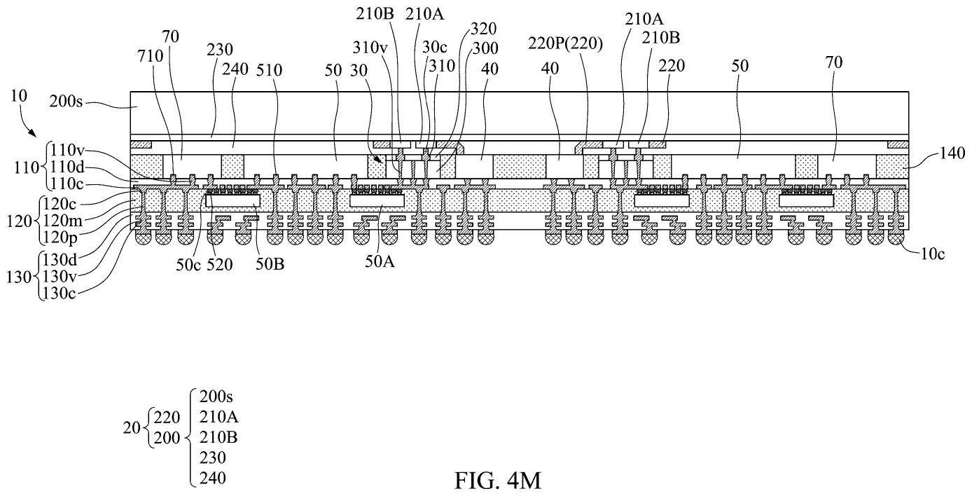

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, and FIG. 4M illustrate various stages of an example of a method for manufacturing a package structure in accordance with some arrangements of the present disclosure.

Referring to FIG. 4A, a carrier strip 200A may be provided, a dielectric layer 230A may be formed on the carrier strip 200A, and an optical channel layer 220′ may be formed on the dielectric layer 230A. The carrier strip 200A may include semiconductor substrate strip. The carrier strip 200A may be formed of or include a silicon wafer or a SOI wafer. Alternatively, the carrier strip 200A may be formed by providing a panel or a panel-level carrier and singulating the panel or the panel-level carrier to form the carrier strip 200A. The optical channel layer 220′ may include silicon. The dielectric layer 230A may include silicon oxide.

Referring to FIG. 4B, optical modulators 210A and photodetectors 210B may be disposed or formed on the dielectric layer 230A and adjacent to the optical channel layer 220′.

Referring to FIG. 4C, an additional optical channel layer may be formed on the optical channel layer 220′ to form an optical transmission structure 220 including at least an optical channel 220P, and a dielectric layer 240A may be formed to cover the optical transmission structure 220 and the dielectric layer 230A. The optical transmission structure 220 may include silicon. The dielectric layer 240A may include silicon oxide.

Referring to FIG. 4D, connection elements 30c may be formed within the dielectric layer 240A to contact the optical modulators 210A and the photodetectors 210B. The connection elements 30c may include one or more electrically conductive materials, e.g., copper. In some arrangements, a chemical mechanical polishing (CMP) operation may be performed to planarize the exposed upper surface. In some arrangements, a plasma operation may be performed to activate the upper surface.

Referring to FIG. 4E, electronic components 30 may be connected to the connection elements 30c. In some arrangements, the electronic components 30 are connected to the dielectric layer 240A and the connection elements 30c through hybrid bonding.

Referring to FIG. 4F, electronic components 40, 50, and 70 may be connected to the dielectric layer 240A, In some arrangements, the electronic components 40, 50, and 70 are connected to the dielectric layer 240A through direct bonding. In some arrangements, dielectric layers of the electronic components 40, 50, and 70 are directly bonded to the dielectric layer 240A.

Referring to FIG. 4G, an encapsulant 140 may be formed to fill gaps between the electronic components 30, 40, 50, and 70. In some arrangements, a polish operation may be performed to expose upper surfaces of the electronic components 30, 40, 50, and 70 from the encapsulant 140.

Referring to FIG. 4H, a conductive structure 110 including a dielectric structure 110d, one or more conductive layers 110c in the dielectric structure 110d, and conductive vias 110v in the dielectric structure 110d may be formed on the encapsulant 140 and the electronic components 30, 40, 50, and 70, and conductive pads 120c and conductive pillars 120p may be formed on the conductive structure 110.

Referring to FIG. 4I, electronic components 50A and 50B may be connected to the conductive structure 110.

Referring to FIG. 4J, an encapsulant 120m may be formed to fill gaps between the conductive pillars 120p, the electronic components 50A, and the electronic components 50B, so as to form a conductive structure 120. In some arrangements, a polish operation may be performed to expose upper surfaces of the conductive pillars 120p and the electronic components 50A and 50B from the encapsulant 120m.

Referring to FIG. 4K, a conductive structure 130 including a dielectric structure 130d, one or more conductive layers 130c in the dielectric structure 130d, and conductive vias 130v in the dielectric structure 130d and electrically connected to the conductive layers 130c may be formed on the conductive structure 120.

Referring to FIG. 4L, connection elements 10c may be formed on the exposed conductive layers 130c. The connection elements may include conductive bumps or solder elements.

Referring to FIG. 4M, a singulation operation may be performed on the wafer-level structure illustrated in FIG. 4L to form a plurality of singulated structures as shown in FIG. 4M. In some arrangements, the carrier strip 200A can be thinned before the singulation operation. Next, referring to FIG. 1A, the singulated structure as shown in FIG. 4M may be connected to a carrier 1000, and optical components 60 may be connected to the optical transmission structure 220. As such, the package structure 1 illustrated in FIG. 1A may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a photonic carrier;
a circuit structure comprising a plurality of electronic components; and
an optical transmission structure separating the circuit structure from the photonic carrier and configured to optically communicate between the electronic components,
wherein the photonic carrier is configured to support the circuit structure and the optical transmission structure and dissipate heat from the electronic components.

2. The package structure as claimed in claim 1, wherein the circuit structure further comprises a bridge element and a redistribution structure electrically connected to the bridge element.

3. The package structure as claimed in claim 2, wherein at least two of the electronic components are electrically connected to each other through the bridge element.

4. The package structure as claimed in claim 1, further comprising an optical coupling component disposed at an edge of the optical transmission structure.

5. The package structure as claimed in claim 1, wherein the electronic components comprise an electronic integrated circuit (EIC) element, a processing element, a storage element, a light-emitting element, or a combination thereof.

6. The package structure as claimed in claim 1, wherein the photonic carrier comprises a carrier, a plurality of optical modulators disposed over the carrier, and a plurality of photodetectors disposed over the carrier.

7. The package structure as claimed in claim 6, wherein a lateral side of the photonic carrier is substantially aligned with a lateral side of the optical transmission structure.

8. A package structure, comprising:
a photonic component;
a plurality of electronic components electrically connected to the photonic component; and
a plurality of processing components electrically connected to each of the corresponding electronic components and configured to transmit signals through the photonic component.

9. The package structure as claimed in claim 8, wherein the photonic component comprises a plurality of optical modulators configured to convert electrical signals from the electronic components to optical signals.

10. The package structure as claimed in claim 8, wherein active surfaces of the electronic components and active surfaces of the processing components face opposite directions.

11. The package structure as claimed in claim 8, wherein the photonic component comprises a plurality of photonic elements and an optical transmission structure optically coupled to the photonic elements, and the optical transmission structure is configured to optically communicate between the processing components.

12. The package structure as claimed in claim 11, wherein the optical transmission structure comprises a first optical channel optically coupling one of the photonic elements to another one of the photonic elements and a second optical channel optically coupling the one of the photonic elements to an optical coupling component.

13. The package structure as claimed in claim 12, further comprising an optical source element, and the optical transmission structure further comprises a third optical channel optically coupling the one of the photonic elements to the optical source element.

14. The package structure as claimed in claim 8, further comprising a redistribution structure electrically connected to the electronic components and the processing components, wherein the photonic component and the redistribution structure are at opposite sides of the electronic components and the processing components.

15. A package structure, comprising:
a plurality of first electronic components configured to generate heat dissipated through a plurality of thermal paths; and
a photonic component comprising a plurality of optical channels configured to transmit optical signals, wherein the optical channels are substantially free from overlapping the thermal paths from a top view perspective.

16. The package structure as claimed in claim 15, wherein the optical channels are substantially free from overlapping the first electronic components from the top view perspective.

17. The package structure as claimed in claim 15, wherein the photonic component further comprises a photonic carrier partially overlapping the thermal paths from the top view perspective.

18. The package structure as claimed in claim 15, wherein the optical channels comprise a first optical channel extending around an edge of at least one of the first electronic components from the top view perspective.

19. The package structure as claimed in claim 15, further comprising a plurality of second electronic components configured to transmit electrical signals to or from the photonic component, wherein the optical channels comprise a first optical channel partially overlapping the second electronic components from the top view perspective.

20. The package structure as claimed in claim 15, wherein the photonic component comprises a first photonic element and a second photonic element optically coupled to each other by at least one of the optical channels.
